(19) United States
(12) Patent Application Publication
(10) Pub. No.: US 2012/0038849 A1
(43) Pub. Date: Feb. 16, 2012

(54) Expanded Heat Sink for Electronic Displays and Method of Producing the Same

(75) Inventors: William Dunn, Alpharetta, GA (US); Tim Hubbard, Alpharetta, GA (US)

(73) Assignee: MANUFACTURING RESOURCES INTERNATIONAL, INC., Alpharetta, GA (US)

(21) Appl. No.: 13/206,596

(22) Filed: Aug. 10, 2011

Related U.S. Application Data
(60) Provisional application No. 61/372,942, filed on Aug. 12, 2010.

(51) Int. Cl. G02F 1/13357; F28F 7/00; H05K 7/20

(52) U.S. Cl. 349/61; 361/704; 165/185

(57) ABSTRACT

An expanded heat sink for transferring heat from an electronic display component to a path of cooling air is disclosed. A continuous sheet may define a series of channels where the cooling air is blown through the channels and along the continuous sheet. When viewed along the path of the cooling air and oriented horizontally, the continuous sheet may define a series of four-sided polygons having top, bottom, left side, and right side portions where either the top or bottom portions are absent from each polygon. The absent top portions may be supplied by a front plate or the rear portion of an electronic display. The absent bottom portions maybe supplied by a rear plate. One or more components of the electronic display may be placed in thermal communication with the sheet and/or front/rear plates to transfer heat from the components to the cooling air.

### CROSS-REFERENCE TO RELATED APPLICATIONS

This application claims priority to U.S. Application No. 61/372,942, filed on Aug. 12, 2010, herein incorporated by reference in its entirety.

### TECHNICAL FIELD

Exemplary embodiments generally relate to cooling systems and in particular to cooling systems for electronic displays.

### BACKGROUND OF THE ART

Conductive and convective heat transfer systems for electronic displays generally attempt to remove heat from the electronic components in a display through the sidewalls of the display. Components such as power modules, which are known for producing a large amount of heat may have a ‘heat sink’ attached to the component which provides an expanded surface area so that heat may be transferred away from the component. These heat sinks have previously been limited to only the size of the power module itself.

Modern displays have become extremely bright, with some LCD backlights producing 1,000-2,000 nits or more. Sometimes, these illumination levels are necessary because the display is being used outdoors, or in other relatively bright areas where the display illumination must compete with other ambient light. In order to produce this level of brightness, illumination devices (ex. fluorescent lamps, LED, organic LED (OLED), light emitting polymer (LEP), organic electro luminescence (OEL), and plasma assemblies) may produce a relatively large amount of heat. Further, the illumination devices require a relatively large amount of power in order to generate the required brightness level. This large amount of power is typically supplied through one or more power supplies for the display. These power supplies may also become a significant source of heat for the display.

Further, previous electronic displays were primarily designed for operation near room temperature. However, it is now desirable to have displays which are capable of withstanding large surrounding environmental temperature variations. For example, some displays are designed for operation at temperatures as low as −22 F and as high as 113 F or higher. When surrounding temperatures rise, the cooling of the internal display components can become even more difficult.

Still further, in some situations radiative heat transfer from the sun through the front portion of the display can also become a source of heat. Furthermore, the market is demanding larger screen sizes for displays. With increased electronic display screen size and corresponding front display surfaces, more heat will be generated and more heat will be transmitted into the displays.

### SUMMARY OF THE EXEMPLARY EMBODIMENTS

Exemplary embodiments relate to a system for cooling various components of an electronic display. The exemplary embodiments may be used to cool the power module(s) or power transformer(s), backlight (if used in the particular display), and other internal components of an electronic display, either alone or in combination. The component(s) may be placed in thermal communication with a continuous conductive sheet which may be placed in the path of cooling air. The heat from the components are distributed throughout the continuous conductive sheet and removed by the cooling air. Some embodiments may place the continuous conductive sheet between a pair of substantially parallel plates (which may also be conductive and may be in thermal communication with the continuous conductive sheet and one or more components).

In one embodiment where the electronic display is a liquid crystal display, power modules and the display backlight may be placed in thermal communication with the continuous conductive sheet. In this way, a single path of cooling air can be used to cool two of the most heat-producing components of a typical LCD. For example, and not by way of limitation, LED arrays are commonly used as the illumination devices for LCD backlights. It has been found that the optical properties of LEDs (and other illumination devices) can vary depending on temperature. Thus, when an LED is exposed to room temperatures, it may output light with a certain luminance, wavelength, and/or color temperature. However, when the same LED is exposed to high temperatures, the luminance, wavelength, color temperature, and other properties can vary. Thus, when a temperature variation occurs across an LED backlight (some areas are at a higher temperature than others) there can be optical inconsistencies across the backlight which can be visible to the observer. By using the exemplary embodiments herein, heat buildup can be evenly distributed across the continuous conductive sheet and removed from the display. This can prevent any potential ‘hot spots’ in the backlight which may become visible to the observer because of a change in optical properties of the LEDs.

The continuous conductive sheet may provide an isolated chamber from the rest of the display so that ambient air can be ingested and used to cool the continuous conductive sheet. This is beneficial for situations where the display is being used in an outdoor environment and the ingested air may contain contaminates (pollen, dirt, dust, water, smoke, etc.) that would damage the sensitive electronic components of the display.

The foregoing and other features and advantages will be apparent from the following more detailed description of the particular embodiments of the invention, as illustrated in the accompanying drawings.

### BRIEF DESCRIPTION OF THE DRAWINGS

A better understanding of an exemplary embodiment will be obtained from a reading of the following detailed description and the accompanying drawings wherein identical reference characters refer to identical parts and in which:

FIG. 1A is a front perspective section view of an exemplary embodiment used to cool an LED backlight;

FIG. 1B is a detailed front perspective section view of insert B from FIG. 1A;

FIG. 2 is a rear perspective view of an embodiment using fans to draw cooling air through the channels;

FIG. 3A is a rear perspective section view of an embodiment where the cooling fans are placed within the continuous conductive sheet and several components are placed within thermal communication with the continuous conductive sheet;

FIG. 3B is a rear perspective section view of insert B from FIG. 3A;

FIG. 4 is a perspective view of one embodiment for the continuous conductive sheet;

FIG. 5A is a side view of one embodiment for the continuous conductive sheet used within an LED-backlit liquid crystal display;

FIG. 5B is a side view of another embodiment for the continuous conductive sheet used to cool a backlight as well as other electrical components; and

FIG. 5C is a side view of another embodiment for the continuous conductive sheet used within an electronic display.

### DETAILED DESCRIPTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Herein the terms ‘front’ and ‘rear’ may be used to describe the relationship between the various elements shown in the various embodiments. The term ‘front’ is used herein to denote a direction towards the intended observer of the electronic display. The term ‘rear’ is used herein to denote a direction away from the intended observer of the electronic display.

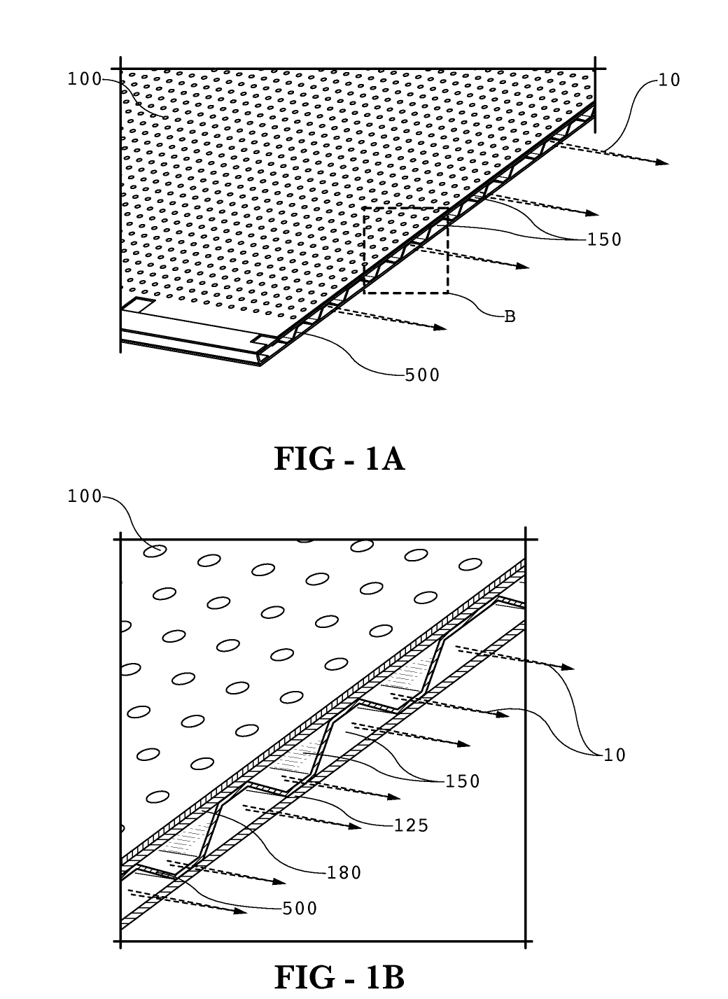

FIG. 1A is a front perspective section view of an exemplary embodiment used to cool an LED backlight 100 (or an LED display). In this embodiment, the continuous conductive sheet 500 is placed adjacent to the LED backlight 100 and used to create a plurality of channels 150. Preferably, the LED backlight 100 is in thermal communication with the continuous conductive sheet 500. Thus, heat which is generated by the LED backlight 100 is transferred to the continuous conductive sheet 500 and removed by cooling air 10.

FIG. 1B is a detailed front perspective section view of insert B from FIG. 1A. In this embodiment, the continuous conductive sheet 500 is placed between a front plate 180 and a rear plate 125 in order to create the channels 150. The front plate 180 is preferably in thermal communication with the LED backlight 100 and the continuous conductive sheet 500. The rear plate 125 may also be in thermal communication with the continuous conductive sheet 500. The thermal communication may be conductive, convective, radiative, or any combination of these. Preferably, the thermal communication is at least conductive.

The LED backlight 100 and front plate 180, front plate 180 and continuous conductive sheet 500, and the continuous conductive sheet 500 and rear plate 125 may be fastened to one another using any number of different techniques, including but not limited to: mechanical fasteners, adhesives, double-sided tape, welding, or other similar techniques. Each component may be attached to one another using similar or different methods. It is preferable that the chosen technique permits thermal communication between the components (if desired). In some embodiments the thermal communication between components may be accomplished by simply placing the components in contact with one-another or in close proximity to one another. Some embodiments may use a combination of the fastening techniques above. Thus, an exemplary embodiment may use both mechanical fasteners as well as an adhesive (preferably a thermally conductive adhesive) or double-sided tape. An exemplary type of double-sided tape would be Very High Bond (VHB™) tape commercially available from 3M™ Saint Paul, Minn. www.3M.com An exemplary form of mechanical fasteners would be rivets or screws/bolts.

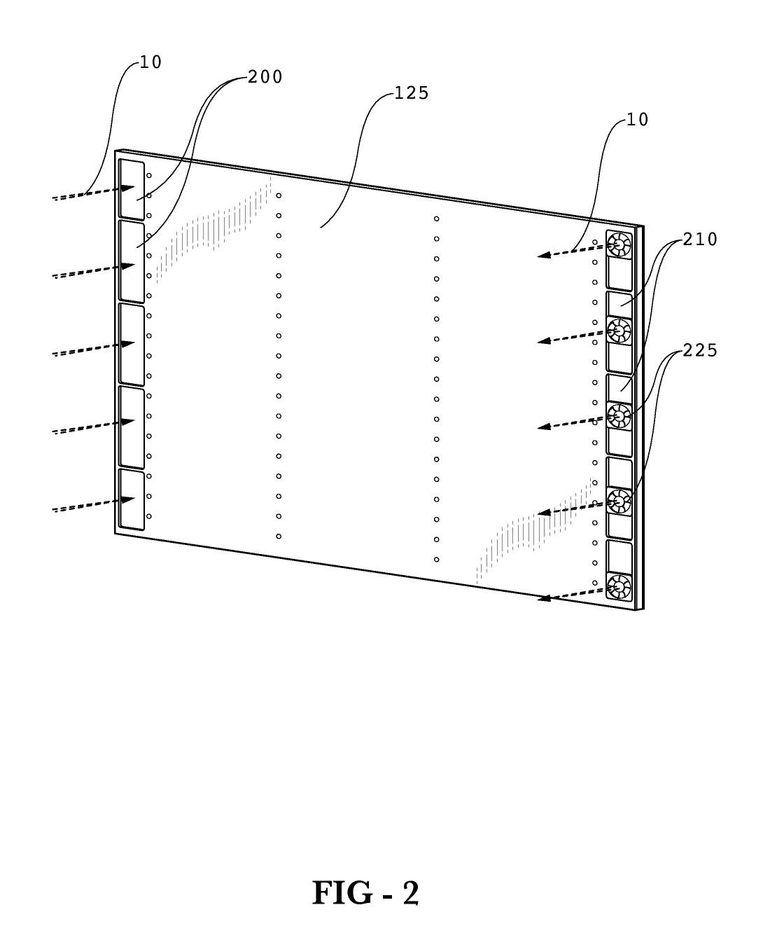

FIG. 2 is a rear perspective view of an embodiment using fans 225 to draw cooling air 10 through the channels 150. Inlet apertures 200 allow the fans 225 to draw cooling air 10 in between the rear plate 125 and front plate 180 and along the channels 150. The cooling air 10 can then be exhausted out of the exit apertures 210. A single fan may be used in some embodiments, while several fans (even more than shown in FIG. 2) could be used in other embodiments. Of course, the fans 225 could instead be placed at the inlet apertures 200 and used to ‘push’ the cooling air 10 through the channels 150 rather than ‘pull’ (as shown in FIG. 2). Further, fans could be placed at both the inlet apertures 200 and exit apertures 210 to both push and pull the cooling air 10 through the system.

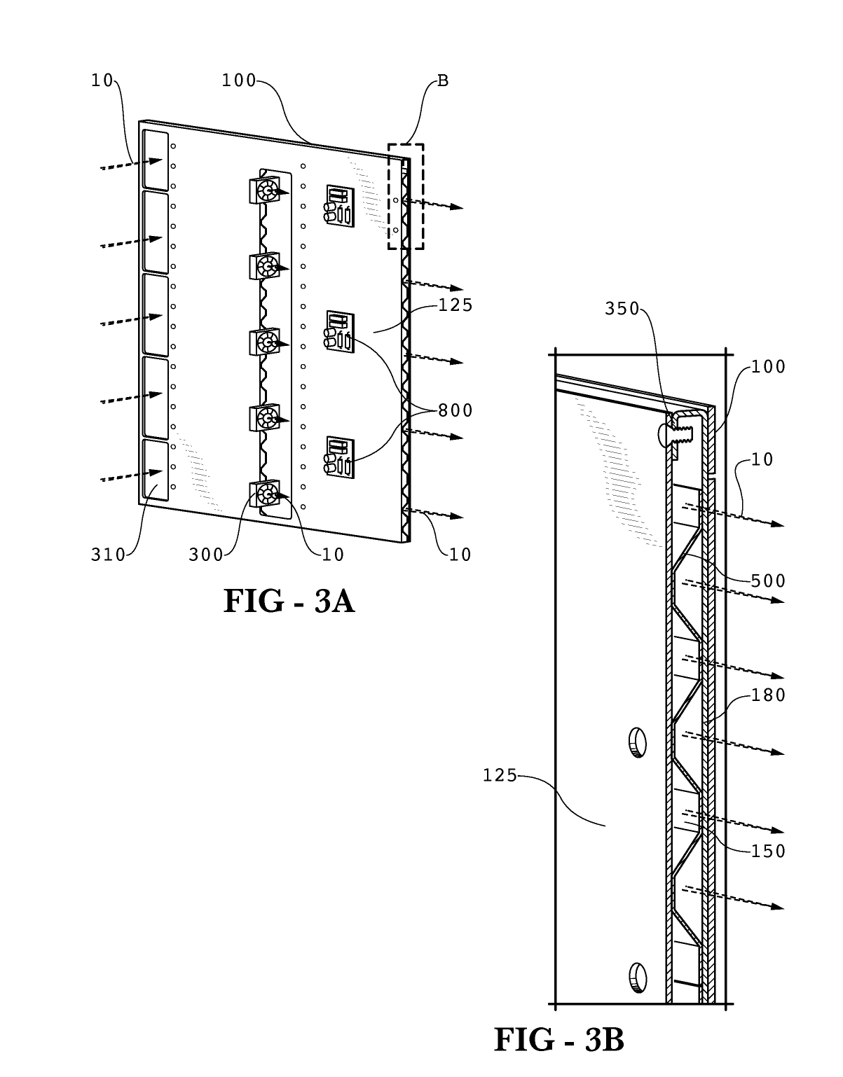

FIG. 3A is a rear perspective section view of an embodiment where the cooling fans 300 are placed within the continuous conductive sheet 500 and electronic components 800 are placed in thermal communication with the continuous conductive sheet 500. In this embodiment, cooling air 10 is drawn into the inlet apertures 310 by fans 300 which are placed along the length of the continuous conductive sheet 500. Thus, in this embodiment the fans 300 perform both a ‘pull’ and ‘push’ of the cooling air 10 through the channels 150. Electronic components 800 may be placed in thermal communication with the continuous conductive sheet 500 by establishing thermal communication between the electronic components 800 and the rear plate 125 (which is preferably in thermal communication with the continuous conductive sheet 500 in this embodiment).

The electronic components 800 may be any electronic component used in an electronic display which generates heat. The electronic components 800 are preferably in electrical communication with the electronic display assembly. Some embodiments may use power supplies/modules or power transformers as the electronic components 800.

FIG. 3B is a rear perspective section view of insert B from FIG. 3A. In this embodiment, the continuous conductive sheet 500 is placed between a front plate 180 and a rear plate 125 in order to create the channels 150. As discussed further below, a front plate 180 may not be necessary in some embodiments. Thus, in some embodiments the continuous conductive sheet 500 may be directly fastened to the rear portion of the LED backlight 100 (or another rear portion of an electronic display, especially an OLED assembly).

In this embodiment, a portion of the front plate 180 overlaps a portion of the rear plate 125 to create an overlap section 350. Here, heat is permitted to transfer directly between the edges of the rear plate 125 and front plate 180 and allows the thermal energy to quickly and evenly spread throughout the plates and the continuous conductive sheet 500.

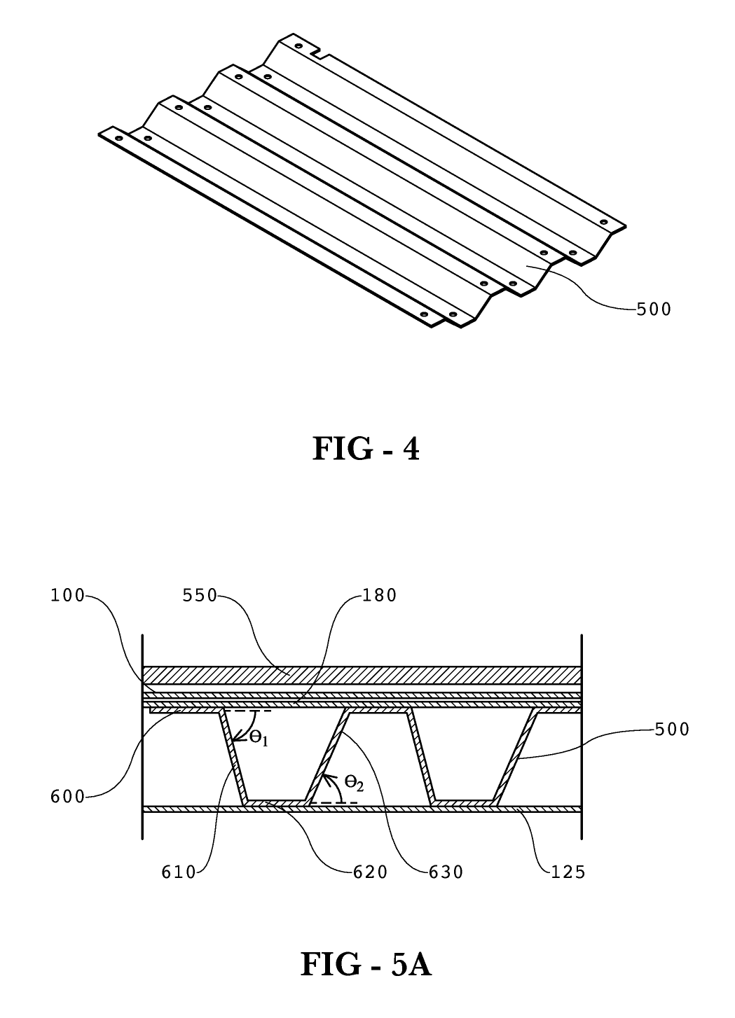

FIG. 4 is a perspective view of one embodiment for the continuous conductive sheet 500.

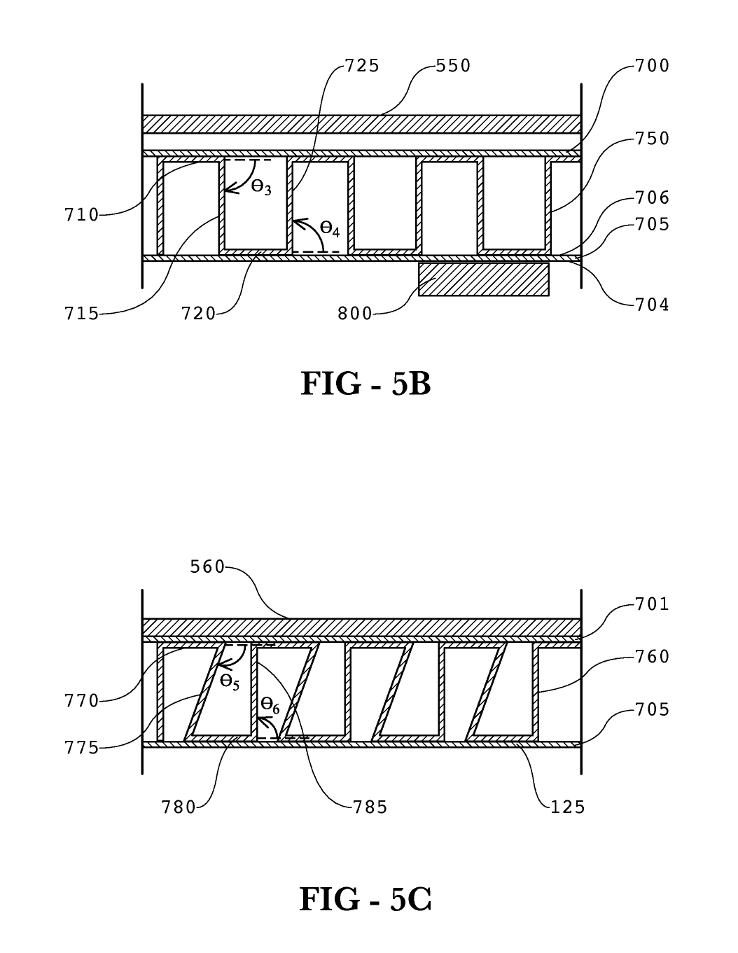

FIG. 5A is a side view of one embodiment for the continuous conductive sheet 500 used within an LED-backlit liquid crystal display. In this embodiment, the LED backlight 100 is attached to and in thermal communication with the front plate 180; which is attached to and in thermal communication with the continuous conductive sheet 500. A liquid crystal assembly 550 is placed in front of the LED backlight 100. The liquid crystal assembly 550 may contain several layers and is well known in the art. Typically, the liquid crystal assembly 550 contains two transparent plates with liquid crystal material sandwiched in between the two plates. An electrode of some type is typically used to orient the liquid crystal material. Additional layers may also be used to orient/polarize light, color filter the light, and provide anti-reflective or protective properties. These layers have not been shown as they are well-known in the art and are not critical to these embodiments of the invention.

Here, the rear plate 125 may not be in thermal communication with the continuous conductive sheet 500 but may only provide structure for the channels and/or structural support to the assembly. Of course, it is preferable that the rear plate 125 and the continuous conductive sheet 500 are in thermal communication so that heat can be more effectively and evenly distributed and removed. Ideally, there should be a low level of thermal resistance between the front and rear sides of the backlight 100. An exemplary embodiment may utilize a metal core PCB with LEDs on the front side and a metallic surface (or otherwise thermally conductive surface) on the rear side.

Generally, the continuous conductive sheet 500 may be described as four continuous portions, which are generally repeated to create the overall structure. For this embodiment, the first portion 600 runs parallel to and adjacent with the front plate 180. The second portion 610 extends from the first portion 600 at angle θ₁ towards the rear plate 125. The third portion 620 extends from the second portion 610 and runs parallel to and adjacent with the rear plate 125. The fourth portion 630 extends from the third portion 620 at angle θ₂ towards the front plate 180. The four portions may then be repeated to create the continuous conductive sheet 500. Thus, the fourth portion 630 may continue to a second series of portions, starting with another portion similar to the previous first portion 600. In some embodiments, angle θ₁ may be substantially equal to angle θ₂. While in other embodiments, angle θ₁ may be different than angle θ₂.

In other words, when oriented horizontally and viewed along the direction of the cooling air (the side view shown in FIG. 5A) the continuous conductive sheet 500 may be formed to create a series of four-sided polygons, each one having a bottom side (portion 620), left side (portion 610), right side (portion 630), and a top side (in this polygon supplied by front plate 180) where either the top or bottom side is absent from each polygon. For the embodiment shown in FIG. 5A, the absent side of the polygon alternates between the top side and bottom side for each adjacent polygon. An exemplary version of the embodiment shown in this figure may be formed of stamped or bent sheet metal.

FIG. 5B is a side view of another embodiment for the continuous conductive sheet 750 used to cool a backlight 700 as well as other electrical components 800. In this embodiment, the continuous conductive sheet 750 is attached to and in thermal communication directly with the backlight 700 (thus, there is no separate front plate used). A liquid crystal assembly 550 is placed in front of the backlight 700, which may be LED driven or may be any other means for illuminating the rear portion of the liquid crystal assembly 550. An additional electrical component 800 is placed in electrical communication with the backlight 700 and/or liquid crystal assembly 550 and is in thermal communication with the rear plate 705. Here, heat which is produced by the electrical component 800 may be transferred to the rear surface 704 of the rear plate 705, where it may then be transferred to the front surface 706 of the rear plate 705. The cooling air can remove the heat from the front surface 706 of the rear plate 705. Additionally, the heat may be transferred from the front surface 706 of the rear plate 705 to the continuous conductive sheet 750 where it may spread throughout the continuous conductive sheet 750 and ultimately removed by the cooling air.

Again, this embodiment of the continuous conductive sheet 750 may be described as four continuous portions, which are generally repeated to create the overall structure. For this embodiment, the first portion 710 runs parallel to and adjacent with the backlight 700. The second portion 715 extends from the first portion 710 at angle θ₃ towards the rear plate 705. The third portion 720 extends from the second portion 715 and runs parallel to and adjacent with the rear plate 705. The fourth portion 725 extends from the third portion 720 at angle θ₄ towards the backlight 700. The four portions may then be repeated to create the continuous conductive sheet 750. Thus, the fourth portion 725 may continue to a second series of portions, starting with another portion similar to the previous first portion 710. In some embodiments, angle θ₃ may be substantially equal to angle θ₄. While in other embodiments, angle θ₃ may be different than angle θ₄. In this particular embodiment, both angles θ₃ and θ₄ are near 90 degrees, or perpendicular to the backlight 700 and rear plate 705 and/or first portion 710 and third portion 720.

In other words, when oriented horizontally and viewed along the direction of the cooling air (the side view shown in FIG. 5B) the continuous conductive sheet 750 may be formed to create a series of four-sided polygons, each one having a bottom side (portion 720), left side (portion 715), right side (portion 725), and a top side (in this polygon supplied by backlight 700) where either the top or bottom side is absent from each polygon. For the embodiment shown in FIG. 5B, the absent side of the polygon alternates between the top side and bottom side for each adjacent polygon. An exemplary version of the embodiment shown in this figure may be formed of stamped or bent sheet metal.

FIG. 5C is a side view of another embodiment for the continuous conductive sheet 760 used within an electronic display. Here, the continuous conductive sheet 760 is attached to and in thermal communication with the front plate 701 which is attached to and in thermal communication with an electronic display assembly 560. In this embodiment, the continuous conductive sheet 760 may be used to cool a type of electronic display that does not require a backlight device. Thus, the electronic display assembly 560 could be, but is not limited to any one of the following types of displays: OLED, LED, light emitting polymer (LEP), organic electro luminescence (OEL), and plasma. The heat which is generated by the electronic display assembly 560 can be transferred to the front plate 701 where it can be transferred to the continuous conductive sheet 760 and removed by the cooling air. Additionally, radiative heat transfer from sunlight can also cause a heat buildup upon the electronic display assembly 560. This heat can also be transferred to the continuous conductive sheet 760 and removed by the cooling air. Here, the rear plate 705 may not be in thermal communication with the continuous conductive sheet 760 but may only provide structure for the channels and/or structural support to the assembly. Of course, it is preferable that the rear plate 705 and the continuous conductive sheet 760 are in thermal communication so that heat can be more effectively and evenly distributed and removed.

Again, this embodiment of the continuous conductive sheet 760 may be described as four continuous portions, which are generally repeated to create the overall structure. For this embodiment, the first portion 770 runs parallel to and adjacent with the front plate 701. The second portion 775 extends from the first portion 770 at angle θ₅ towards the rear plate 705. The third portion 780 extends from the second portion 775 and runs parallel to and adjacent with the rear plate 705. The fourth portion 785 extends from the third portion 780 at angle θ₆ towards the front plate 701. The four portions may then be repeated to create the continuous conductive sheet 760. Thus, the fourth portion 785 may continue to a second series of portions, starting with another portion similar to the previous first portion 770. In some embodiments, angle θ₅ may be substantially equal to angle θ₆. While in other embodiments, angle θ₅ may be different than angle θ₆.

In other words, when oriented horizontally and viewed along the direction of the cooling air (the side view shown in FIG. 5C) the continuous conductive sheet 760 may be formed to create a series of four-sided polygons, each one having a bottom side (portion 780), left side (portion 775), right side (portion 785), and a top side (in this polygon supplied by front plate 701) where either the top or bottom side is absent from each polygon. For the embodiment shown in FIG. 5C, the absent side of the polygon alternates between the top side and bottom side for each adjacent polygon. An exemplary version of the embodiment shown in this figure may be formed of bent sheet metal.

Electronic displays are produced in a variety of sizes and orientations, including but not limited to both landscape and portrait orientations. Any of the embodiments herein can be used to cool the various types, sizes, and orientations of electronic displays. Further, the channels may be oriented in a vertical manner, and the cooling air may travel from top to bottom or from bottom to top. Still further, the channels may be oriented in a horizontal manner, and the cooling air can travel left to right or right to left.

While the embodiments of the continuous conductive sheet have been generally described as containing four portions which repeat themselves, other embodiments could use a mixture of different designs. Thus, some embodiments may not repeat the same four portions over and over. Some embodiments could use four portions from the continuous conductive sheet 750 of FIG. 5B, followed by four portions from the continuous conductive sheet 500 of FIG. 5A. Of course, any number of different combinations could be used, depending on the materials and manufacturing process used to construct the particular continuous conductive sheet.

It should be noted that the embodiments herein do not require that a singular continuous conductive sheet is used to cool the entire electronic display. A plurality of smaller continuous conductive sheets may be used in order to cool the display. The smaller continuous conductive sheets may be connected to each other and in thermal communication with one another or they may be spaced apart from one another. Thus, as used herein the term ‘continuous’ does not require that the entire display is cooled with a single conductive sheet. The term ‘continuous’ as used herein defines a single element that can be placed between two substantially planar objects to create at least two channels.

Further, the term ‘thermal communication’ as used herein does not require direct thermal communication, i.e. there may be intermediate devices or layers in-between the two components which are still considered to be in ‘thermal communication.’ Conductive heat transfer is one type of thermal communication and is preferable with the exemplary embodiments herein. Convective thermal communication is one type of thermal communication which is preferable between the continuous conductive sheet and the cooling air.

The continuous conductive sheets have been shown herein with relatively constant cross-sectional thicknesses but this is also not required. Some portions of the continuous conductive sheets may be thicker or thinner than other portions and some may even contain fins or additional extended surface areas for removing the absorbed heat.

It is preferable that the front plate, rear plate, and continuous conductive sheet are comprised of materials which are thermally conductive. Metals have been found to be exemplary materials for these components. More specifically, sheet metals and even more specifically aluminum sheet metals are preferable. However, many thermally conductive plastics and composite materials can also perform adequately. Specifically, polypropylene sheets would be within the scope of the various embodiments.

In an exemplary embodiment, the front and rear plates would provide a gaseous and contaminate barrier between the space between them (containing the continuous conductive sheet) and the rest of the display. If the plates provide an adequate barrier, ambient air may be ingested as cooling air 10 and the risk of contaminates entering the portions of the display containing the sensitive electronic components may be reduced or eliminated.

As noted above, many illumination devices (especially LEDs and OLEDs) may have performance properties which vary depending on temperature. When ‘hot spots’ are present within a backlight or illumination assembly, these hot spots can result in irregularities in the resulting image which might be visible to the end user. Thus, with the embodiments described herein, the heat which may be generated by the backlight assembly can be distributed (somewhat evenly) throughout the various ribs and thermally-conductive surfaces to remove hot spots and cool the backlight.

The cooling system may run continuously. However, if desired, temperature sensing devices (not shown) may be incorporated within the electronic display to detect when temperatures have reached a predetermined threshold value. In such a case, the various cooling fans may be selectively engaged when the temperature in the display reaches a predetermined value. Predetermined thresholds may be selected and the system may be configured to advantageously keep the display within an acceptable temperature range. Typical thermostat assemblies can be used to accomplish this task. Thermocouples may be used as the temperature sensing devices.

It is to be understood that the spirit and scope of the disclosed embodiments provides for the cooling of many types of displays. By way of example and not by way of limitation, embodiments may be used in conjunction with any of the following: LCD (all types), light emitting diode (LED), organic light emitting diode (OLED), field emitting display (FED), light emitting polymer (LEP), organic electro luminescence (OEL), plasma displays, and any other type of flat panel electronic display. Furthermore, embodiments may be used with displays of other types including those not yet discovered. In particular, it is contemplated that the system may be well suited for use with full color, flat panel OLED displays. Exemplary embodiments may also utilize large (55 inches or more) LED backlit, high definition (1080i or 1080p or greater) liquid crystal displays (LCD). While the embodiments described herein are well suited for outdoor environments, they may also be appropriate for indoor applications (e.g., factory/industrial environments, spas, locker rooms) where thermal stability of the display may be at risk.

Although fans are shown with some of the embodiments herein, they are not required for all embodiments. While forced convection (using fans) is preferable, natural or un-forced convection (no fans) may also produce acceptable results and is within the scope of the invention.

The relative sizing of each component shown in the figures is not to be interpreted as a requirement of the invention or that they are accurately drawn to scale. Some components have been enlarged for clarity. Other components have been simplified for clarity.

Having shown and described preferred embodiments, those skilled in the art will realize that many variations and modifications may be made to affect the described embodiments and still be within the scope of the claimed invention. Additionally, many of the elements indicated above may be altered or replaced by different elements which will provide the same result and fall within the spirit of the claimed invention. It is the intention, therefore, to limit the invention only as indicated by the scope of the claims.

1. An expanded heat sink for transferring heat from an electronic display component to a path of cooling air, the expanded heat sink comprising:
a continuous sheet when viewed along the path of the cooling air and oriented horizontally, defines a series of four-sided polygons having top, bottom, left side, and right side portions where either the top or bottom portions are absent from each polygon.

2. The heat sink of claim 1 wherein:
the absent portion of the polygon alternates between the top and bottom portion for each adjacent polygon.

3. The heat sink of claim 1 wherein:
the four-sided polygons are trapezoids.

4. The heat sink of claim 1 wherein:
the top and bottom portions are substantially parallel.

5. The heat sink of claim 1 wherein:
the four-sided polygons are rectangles.

6. The heat sink of claim 1 further comprising:
a front plate placed above the continuous sheet; and
a rear plate place below the continuous sheet.

7. The heat sink of claim 6 wherein:
the front plate is placed so as to supply the missing top portion of the polygons; and
the rear plate is placed so as to supply the missing bottom portion of the polygons.

8. A liquid crystal display (LCD) comprising:
the heat sink of claim 6;
an LED backlight placed above and in thermal communication with the front plate; and
a liquid crystal assembly placed above the LED backlight.

9. The LCD of claim 8 further comprising:
a fan positioned to draw cooling air between the front plate and rear plate and along the continuous sheet.

10. The LCD of claim 8 wherein:
the LED backlight is placed in conductive thermal communication with the front plate.

11. An expanded heat sink for transferring heat from an electronic display component to a path of cooling air, the expanded heat sink comprising:
a substantially planar front plate;
a substantially planar rear plate placed parallel to the front plate; and
a continuous sheet placed between the front and rear plates to define a series of channels for accepting the cooling air.

12. The heat sink of claim 11 wherein:
the continuous sheet contains a series of four portions:
the first portion running substantially parallel to the front plate,
the second portion extending from the first portion and towards the rear plate at a first angle,
the third portion extending from the second portion and substantially parallel to the rear plate, and
the fourth portion extending from the third portion and towards the front plate at a second angle.

13. The heat sink of claim 12 wherein:
the first portions are in contact with the front plate, and
the third portions are in contact with the rear plate.

14. The heat sink of claim 12 wherein:
the first and second angles are substantially equal.

15. The heat sink of claim 12 wherein:
the first and second angles are each less than ninety degrees.

16. An electronic display comprising:
the heat sink of claim 11;
an electronic display assembly placed in front of and in thermal communication with the front plate; and
a fan positioned to draw cooling air through the channels.

17. The electronic display of claim 16 further comprising:
an electrical component in conductive thermal communication with the rear plate.

18. The electronic display of claim 17 wherein:
the electrical component is any one of the following: power module, power supply, and power transformer.

19. A liquid crystal display (LCD) comprising:
the heat sink of claim 1;
an LED backlight placed above and in thermal communication with the continuous sheet;
a liquid crystal assembly placed above the LED backlight;
a rear plate placed behind and in thermal communication with the continuous sheet; and
a fan positioned to draw cooling air between the LED backlight and rear plate and along the continuous sheet.

20. The LCD of claim 19 further comprising:
an electrical component in conductive thermal communication with the rear plate.
